(19) United States
(12) Patent Application Publication
(10) Pub. No.: US 2006/0066460 A1
(43) Pub. Date: Mar. 30, 2006

(54) Arithmetic unit

(75) Inventor: Hiroaki Suzuki, Tokyo (JP)

Correspondence Address: McDermott Will & Emery LLP, 600 13th Street, N.W., Washington, DC, 20005-3096, US

(73) Assignee: Renesas Technology Corp.

(21) Appl. No.: 11/231,804

(22) Filed: Sep. 22, 2005

(30) Foreign Application Priority Data
Sep. 28, 2004 (JP) 2004-281200
Jul. 28, 2005 (JP) 2005-218694

(51) Int. Cl. H03M 7/00

(52) U.S. Cl. 341/50

(57) ABSTRACT

The present invention provides an arithmetic unit performing a saturation process that can reduce a delay time relating to an arithmetic process and a saturation process, thereby being capable of increasing a processing speed. An arithmetic unit according to the present invention includes an arithmetic processing section that performs an adding or subtracting operation of a first input operand and a second input operand and outputs the arithmetic result, a saturation anticipating section that anticipates whether the arithmetic result is within a representation range of a predetermined bit length based upon the first input operand and the second input operand, and outputs a saturation anticipating signal, and a selecting section selecting that the maximum value or minimum value within the representation range of the predetermined bit length is made to be the output result in case where the arithmetic result is anticipated not to be within the representation range of the predetermined bit length in the saturation anticipating signal from the saturation anticipating section, while selecting that the arithmetic result is made to be the output result in case where the arithmetic result is anticipated to be within the representation range of the predetermined bit length in the saturation anticipating signal. Herein, the saturation anticipating section is operated in parallel with respect to the arithmetic processing section.

### BACKGROUND OF THE INVENTION

1. Field of the Invention

The present invention relates to an arithmetic unit, and more particularly to an arithmetic unit performing a saturation process.

2. Description of the Background Art

There may be the case in DSP (Digital Signal Processor) that an output is made with a representation range of a bit length different from a representation range of an inputted bit length depending upon a device to be outputted or data type. For example, inputted data within the representation range of 40-bit length may be subject to add-subtract process to be outputted as data within the representation range of 16-bit length in the DSP. In case where the data within the representation range of 40-bit length is outputted as data within the representation range of 16-bit length, it is considered that the output data may cause overflow depending upon the inputted data. As a countermeasure for this overflow, a saturation process is generally performed.

Specifically, in an arithmetic unit used in a conventional DSP, it is checked whether the arithmetic result of the add-subtract process is within the representation range of 16-bit length or not, and in case where the arithmetic result is not within the representation range of 16-bit length as a result of this check, the maximum positive value or negative minimum value within the representation range of 16-bit length is outputted as the output data according to a sign. For example, supposing that the adding result of the input operand S0[0:39] and S1[0:39] is dtsum[0:39]. It should be noted that the expression “[0:39]” is a bus representation. In this case, it is a case where not all results outside the representation range of 16-bit length (high-order 25 bits including 1 bit representing a sign) take “0” that the arithmetic result exceeds the representation range of 16-bit length. Specifically, the dtsum[0:39] wherein dtsum[0] =1′b0 and dtsum[1:24]!=24′h000000 exceeds the representation range of 16-bit length. It should be noted that “==” represents a condition operator providing that both sides agree with each other, “!=” represents a condition operator providing that both sides do not agree with each other, “1′b” represents a 1-bit binary representation and “24′h” represents a 24-bit hexadecimal representation. Further, dtsum[0] represents a sign wherein “0” thereof represents positive and “1” thereof represents negative.

In case where dtsum[0:39] exceeds the representation range of 16-bit length, the saturation process is performed, whereby the outputted dtsum[0:39] equals 40h′0000007FFF that is the positive maximum value within the representation range of 16-bit length. Further, dtsum[0:39] wherein dtsum[0]==1′b1 and dtsum[1:24]!=24′hFFFFFF is a negative number and exceeds the representation range of 16-bit length. In case where dtsum[0:39] exceeds the representation range of 16-bit length, the saturation process is performed, whereby the outputted dtsum[0:39] equals 40h′FFFFFF8000 that is the minimum value within the representation range of 16-bit length.

The representation range of the outputted data is not limited to 16-bit length, but it may be 32-bit length. Even in the representation range of 32-bit length, dtsum[0:39] wherein dtsum[0]==1′b0 and dtsum[1:8]!=8′h00 exceeds the representation range of 32-bit length, like the aforesaid case. In case where dtsum[0:39] exceeds the representation range of 32-bit length, the saturation process is performed, whereby the outputted dtsum[0:39] equals 40h′007FFFFFFF that is the positive maximum value within the representation range of 32-bit length. Further, dtsum[0:39] wherein dtsum[0]==1′b1 and dtsum[1:8]!=8′hFF is a negative number and exceeds the representation range of 32-bit length. In case where dtsum[0:39] exceeds the representation range of 32-bit length, the saturation process is performed, whereby the outputted dtsum[0:39] equals 40h′FF80000000 that is the minimum value within the representation range of 16-bit length.

A conventional arithmetic unit disclosed in Japanese Patent Application Laid-Open No. 04-167170 (1992) or Japanese Patent Application Laid-Open No. 04-286023 (1992) shows the case where the aforesaid algorithm is mounted as it is to a hardware, wherein the adding process and saturation process are executed in serial. Specifically, a path for checking whether it is within the representation range of 16-bit length by checking high-order 25 bits after the execution of the adding process of the 40-bit input operand becomes a critical path.

In general, a pipeline processing for performing a process in parallel is carried out in an arithmetic unit in a high-speed microprocessor or general-purpose DSP. However, an effect by this pipeline processing is difficult to be shown in an adder, so that the adder may frequently decide a clock cycle of an arithmetic unit. Further, as explained in the background art, there arises a problem of further delaying the clock cycle by the saturation process if the saturation process is performed by connecting the adding process in serial.

When 25-bit logic operation is executed in the saturation process, it takes a processing time of about 20 to 50% of the 40-bit adding process, specifically. Therefore, an arithmetic unit performing the saturation process requires a processing time about 1.2 to 1.5 times that of an arithmetic unit not performing the saturation process. It is considered that the saturation process itself is subject to the pipeline processing, but this has a problem of causing a data hazard or the like, thereby entailing a problem of deteriorating a system performance even by using the pipeline processing to the saturation process of the arithmetic unit.

### SUMMARY OF THE INVENTION

The present invention aims to provide an arithmetic unit performing a saturation process that reduces a delay time relating to an arithmetic process and saturation process, thereby being capable of increasing a processing speed.

An arithmetic unit according to one aspect of the present invention includes an arithmetic processing section, saturation anticipating section and selecting section. The arithmetic processing section performs an adding or subtracting operation of a first input operand and a second input operand and outputs the arithmetic result. The saturation anticipating section anticipates whether the arithmetic result is within the representation range of a predetermined bit length based upon the first input operand and the second input operand and outputs a saturation anticipating signal. The selecting section selects that the maximum value or minimum value within the representation range of the predetermined bit length is made to be the output result in case where the arithmetic result is anticipated not to be within the representation range of the predetermined bit length in the saturation anticipating signal from the saturation anticipating section, while selects that the arithmetic result is made to be the output result in case where the arithmetic result is anticipated to be within the representation range of the predetermined bit length in the saturation anticipating signal. The saturation anticipating section is operated in parallel with respect to the arithmetic processing section.

The arithmetic unit of the present invention is configured such that the saturation anticipating section is operated in parallel with respect to the arithmetic processing section, thereby providing an effect of reducing the processing delay at the saturation anticipating section and increasing a processing speed of the arithmetic unit.

Further, an arithmetic unit according to another aspect of the present invention includes an address calculating section and a hit determining section. The address calculating section is an arithmetic unit used for an address modification section of a memory. It operates a memory address based upon a base value and address value after a predetermined processing is performed and first carry information. The hit determining section determines whether a target address performing an access and the memory address agree with each other or not based upon second carry information operated from predetermined low-order bit of the base value and the address value and the first carry information and predetermined high-order bit of the base value and the address value, and outputs the determination result as a Hit signal. The hit determining section is operated in parallel with respect to the address calculating section.

The arithmetic unit according to another aspect of the present invention is configured such that the hit determining section is processed in parallel with the address calculating section, thereby providing an effect of being capable of outputting the Hit signal with high speed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram showing a configuration of an arithmetic unit according to a first embodiment of the present invention;

FIG. 2 is a view showing a relationship between an input operand and an arithmetic result according to the first embodiment of the present invention;

FIG. 3 is a diagram showing a configuration of a logic circuit that operates a Zero anticipating bit according to the first embodiment of the present invention;

FIG. 4 is a diagram showing a configuration of a logic circuit that operates a One anticipating bit according to the first embodiment of the present invention;

FIG. 5 is a diagram showing a configuration of a saturation processing section according to the first embodiment of the present invention;

FIG. 6 is a diagram showing a configuration of a saturation processing section according to a second embodiment of the present invention;

FIG. 7 is a diagram showing a configuration of a saturation processing section according to a third embodiment of the present invention;

FIG. 8 is a diagram showing a configuration of a logic circuit that operates a Zero anticipating bit according to a fourth embodiment of the present invention;

FIG. 9 is a diagram showing a configuration of a logic circuit that operates a One anticipating bit according to the fourth embodiment of the present invention;

FIG. 10 is a diagram showing a configuration of a logic circuit that operates a Zero anticipating bit and One anticipating bit according to a fifth embodiment of the present invention;

FIG. 11 is a layout view of a semiconductor device;

FIG. 12 is a block diagram of an address modification section and a cache determining section;

FIG. 13 is a block diagram of an address modification section according to a sixth embodiment of the present invention;

FIG. 14 is a block diagram of another address modification section according to the sixth embodiment of the present invention;

FIG. 15 is a block diagram of an address modification section according to a seventh embodiment of the present invention;

FIG. 16 is a block diagram of an address modification section according to an eighth embodiment of the present invention;

FIG. 17 is a diagram for explaining a TLB according to a ninth embodiment of the present invention; and

FIG. 18 is a diagram for explaining a cache memory according to a tenth embodiment of the present invention.

### DESCRIPTION OF THE PREFERRED EMBODIMENTS

### First Embodiment

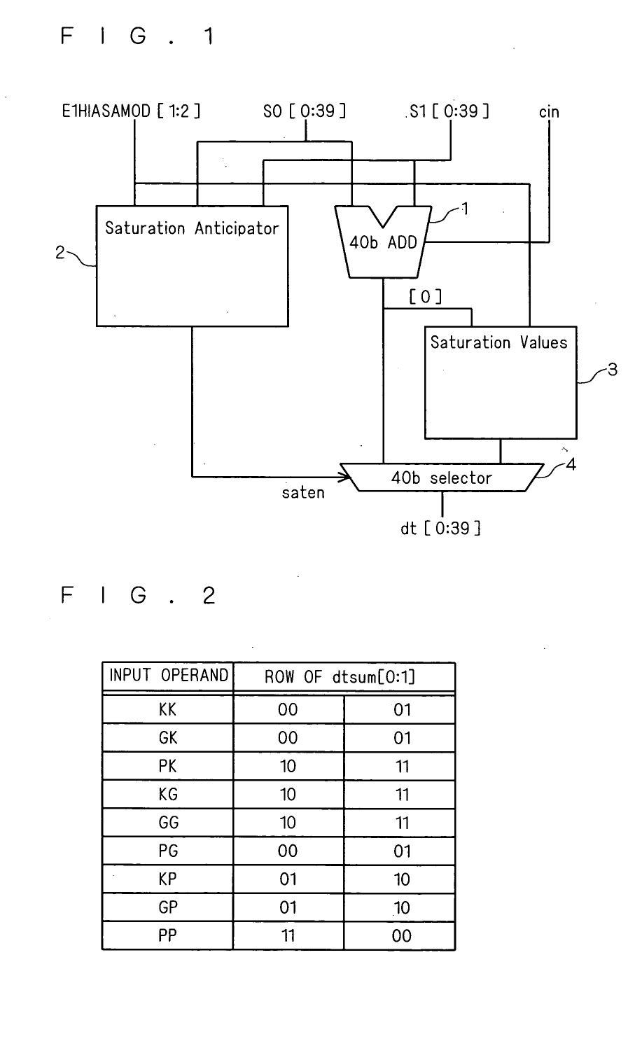

FIG. 1 is a block diagram showing an arithmetic unit according to this embodiment. The arithmetic unit shown in FIG. 1 has an adder 1, serving as an arithmetic processing section, that performs an add operation of input operands S0[0:39] and S1[0:39] and outputs the arithmetic result dtsum[0:39] and a saturation anticipator 2 that anticipates whether the arithmetic result of the adder 1 is within the representation range of a predetermined bit length (e.g., 16 bit length) or not from the input operands S0[0:39], S1[0:39] and E1HIASAMOD [1:2] and outputs a saturation anticipating signal (saten), wherein the adder 1 serving as an arithmetic processing section and the saturation anticipator 2 are configured to operate in parallel. It should be noted that E1HIASAMOD [1:2] is a signal for setting whether the saturation process including the saturation anticipator 2 is enabled or disabled.

Further, the arithmetic unit shown in FIG. 1 is provided with a saturation values generating section 3 that generates the maximum value or minimum value of the representation range of the predetermined bit length from the arithmetic result (the section dtsum[0] showing the sign of the arithmetic result) of the adder 1 and E1HIASAMOD [1:2], and a selecting section 4 that selects the arithmetic result from the adder 1 or the maximum (minimum) value generated at the saturation values generating section 3 based upon the saturation anticipating signal (saten) from the saturation anticipator 2 and defines the selected one as the output result (dt[0:39]).

Subsequently, the operation of the arithmetic unit shown in FIG. 1 will be explained hereinafter. The arithmetic unit according to this embodiment will be explained by taking, as one example, a case wherein input operands S0[0:39] and S1[0:39] of 40 bits are outputted in the representation range of 16-bit length or 32-bit length. Firstly, the saturation anticipator 2 anticipates a saturation condition of whether they are within the representation range of 16-bit length or not. This is specifically the same as the method explained in the background art. Namely, it is anticipated whether all of 25 bits of dtsum[0:24] outputted from the adder 1 is All “0” or All “1” at the saturation anticipator 2.

Specifically, whether dtsum[i] is “0” or “1” is anticipated from the input operands S0[i:i+1] and S1[i:i+1]. The adder 1 executes the operation of dtsum[0:24]=S0[0:24]+S1[0:24]+Cin. Cin represents a carry input. The saturation anticipator 2 according to this embodiment generates a Zero anticipating bit string E0[0:24] wherein high-order 25 bits of the arithmetic result dtsum[0:39] becomes “0”, whereby AND of the bit string is made &E0[0:24] and represented as up24a0. It should be noted that E0[0:24] has a corresponding bit of “1” in case where the bit of dtsum[0:24] is “0”.

Similarly, the saturation anticipator 2 according to this embodiment generates a One anticipating bit string E1[0:24] wherein high-order 25 bits of the arithmetic result dtsum[0:39] becomes “1”, whereby AND of the bit string is made &El[0:24] and represented as up24a1. It should be noted that E1[0:24] has a corresponding bit of “1” in case where the bit of dtsum[0:24] is “1”. The saturation anticipator 2 further obtains Sat16 that is a saturation anticipating bit from the anticipated up24a0 and up24a1. Although Zero anticipating bit string E0[0:24] and One anticipating bit string E1[0:24] are separately provided in the above disclosure, they may be saturation anticipating bit string without making a distinction between them.

Subsequently, the method for obtaining the Zero anticipating bit string E0[0:24] will be explained. Firstly, Propagate signal (P), Generate signal (G) and Kill signal (K) used in a general logical operation in an adder are defined as a Formula 1.
P=SOˆS1; G=S)&S1; K=^{˜}(SO|S1); (1)

In the Formula 1, “ˆ” represents an exclusive-OR of a binary operator, “&” represents AND of the binary operator, “|” represents OR of the binary operator and “^{˜}” represents an inverted operator.

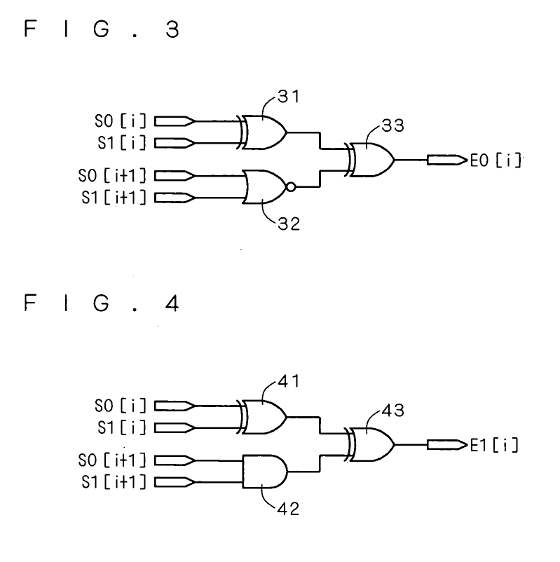

Considering the case about the high-order two-bit dtsum[0:1] of dtsum[0:24], all combinations of the input operands S0[0:1] and S1[0:1] inputted to the adder represented by the P signal, G signal and K signal are those shown in the left column in FIG. 2. The right two columns in FIG. 2 show the arithmetic results dtsum[0:1] of the input operands S0[0:1] and S1[0:1] represented by the P signal, G signal and K signal. The reason why there are two right columns in FIG. 2 is due to the difference in the carry input (Cin). Specifically, the case of Cin=0 is listed in the first column and the case of Cin=1 is listed in the second column.

From the relationship between the input operands S0[0:1], S1[0:1] and the arithmetic result dtsum[0:1] shown in FIG. 2, any dtsum[0] becomes “0” regardless of the carry input state, in case where the input is KK, GK or PG From this, it is anticipated that the dtsum[0] always becomes “0” in case where the input is KK, GK or PG However, there is a probability that the dtsum[0] takes either “0” or “1” depending upon the carry input state, in case where the input is KP, GP or PP. In case where the input is KP or GP, the dtsum[1] always takes “1” even if the dtsum[0] takes “0”. Therefore, from the viewpoint of anticipating whether the dtsum[0:24] is All “0” or not, it does not matter to include the cases of KP and GP in the input for anticipating that the dtsum[0] is not “0”.

On the other hand, in case where the input is PP, even if the dtsum[0] is anticipated to be “0” and this anticipation is wrong, the Zero anticipating bit string E0[i]=0 and AND &E0[0:24]=0, since it depends on the appearance of PK input combination in the anticipation of dtsum[1:24]. Further, in case where P[0:24] is All “1”, if E0[1:24] can be correctly obtained, it can be determined whether dtsum[0:24] becomes All ”0” or All “1” from this result. From the above-mentioned viewpoint, the case of PP can be included in the input for anticipating that dtsum[0] is “0”.

From the aforesaid explanation, the cases wherein &E0[0:24]=1 (dtsum[0:24] is All “0”) is established are those wherein the input operands are KK, GK and PP. The following Formula 2 represents the equation of Zero anticipating bit E0[i] at ith bit.

$$\begin{matrix}E0 [ i ] = ( K [ i ] \& K [ i + 1 ] ) \vert ( G [ i ] \& K [ i + 1 ] ) \vert \\ ( P [ i ] \& G [ i + 1 ] ) \vert P [ i ] \& P [ i + 1 ] ) \\ = {(}^{\sim} P [ i ] \& K [ i + 1 ] ) \text{\vert} ( {P [ i ] \& }^{\sim} K [ i + 1 ] ) \\ = P [ i ] \hat{} K [ ⅈ + 1 ]\end{matrix} \qquad ( 2 )$$

Specifically, the Formula 2 is applied to the process for anticipating whether the arithmetic result of 40-bit is within the representation range of 16-bit, the following Formula 3 is obtained.
E0[0:23]=P[0:23]ˆK[1:24] (3)

Since E0[24] at 24th bit that is the least significant bit is required to be separately considered, the Formula 3 represents Zero anticipating bit string E0[0:23] from the 0th bit to the 23rd bit. E0[24] is represented as the Formula 4.

$$\begin{matrix}E0 [ 24 ] {=}^{\sim} P [ 24 ] \hat{} Co [ 25 ] \\ {=}^{\sim} dtsum [ 24 ]\end{matrix} \qquad ( 4 )$$

Co[25] represents here a carry output at the 25th bit. The method for correctly anticipating E0[24] has not been found at present, so that it is necessary to anticipate a carry from a low order. Specifically, ^{˜}P[24]ˆCo[25] becomes equal to the inverted result of the dtsum[24] that is the output from the adder.

Similarly, since the dtsum[0:1] takes the row of “11” in case where the input operand is PK, KG, GG or PP from the relationship shown in FIG. 2, One anticipating bit E1[i] at ith bit and One anticipating bit string E1[0:23] that is the specific example are obtained as represented in the Formula 5.

$$\begin{matrix}E1 [ ⅈ ] = \begin{matrix}( P [ i ] \& K [ i + 1 ] ) \vert ( K [ i ] \& G [ ⅈ + 1 ] ) \vert \\ ( G [ i ] \& G [ i + 1 ] ) \vert P [ i ] \& P [ i + 1 ] )\end{matrix} \\ = {(}^{\sim} P [ i ] \& G [ i + 1 ] ) \text{\vert} ( {P [ i ] \& }^{\sim} G [ i + 1 ] ) \\ = P [ i ] \hat{} G [ i + 1 ] \\ E1 [ 0 : 23 ] = P [ 0 : 23 ] \hat{} G [ 1 : 24 ] \\ E1 [ 24 ] = P [ 24 ] \hat{} Co [ 25 ] \\ = dtsum [ 24 ]\end{matrix} \qquad ( 5 )$$

The method for correctly anticipating E1[24] represented in the Formula 5 has not been found at present, so that it is necessary to anticipate a carry from a low order. Specifically, P[24]ˆCo[25] becomes equal to the dtsum[24] that is the output from the adder.

As described above, the saturation anticipating bit Sat16 of the representation range of 16-bit length is obtained from the Zero anticipating bit string E0[0:24] and One anticipating bit string E1[0:24] as represented in the Formula 6.
Sat16 =^{˜}((&E0[0:23])&^{˜}dtsum[24]|(&E1[0:23])&dtsum[24]) (6)

The saturation anticipating bit Sat32 of the representation range of 32-bit length is similarly obtained as represented in the Formula 7 by using the aforesaid method.
Sat32=^{˜}((&E0[0:7])&^{˜}dtsum[8]|(&E1[0:7])&dtsum[8]) (7)

Subsequently, E1HIASAMOD[1:2] supplies to the saturation anticipator 2 a signal of 2′00 that means “not performing saturation process”, a signal of 2′b10 that means “performing saturation process to 16-bit length”, a signal of 2′b01 that means “performing saturation process to 32-bit length”, and a signal of 2′b11 that means “inhibition state”, for example. Among these signals, 2′b10 that means “performing saturation process to 16-bit length” is an enable signal (Sat16en) that instructs to perform the saturation process so as to bring the arithmetic result within the representation range of 16-bit length, while the signal 2′b01 that means “performing saturation process to 32-bit length” is an enable signal (Sat32en) that instructs to perform the saturation process so as to bring the arithmetic result within the representation range of 32-bit length. The saturation anticipator 2 generates the saturation anticipating signal (saten) represented in the Formula 8 from the saturation anticipating bit Sat16, Sat32 and enable signals Sat16en and Sat32en, and supplies the same to the selecting section 4.
saten=sat16&sat16en|sat32&sat32en (8)

When the saturation anticipating signal (saten) is “1”, the selecting section 4 outputs the saturation value according to the sign (dtsum[0]) of the arithmetic result as the output result dt[0:39]. In case where the saturation anticipating signal (saten) is “0”, the selecting section 4 outputs the arithmetic result of the adder 1 as the output result dt[0:39] as it is.

As described above, the saturation anticipator according to this embodiment is configured to generate the saturation anticipating bit string E0[i] (Zero anticipating bit) and E1[i] (One anticipating bit) based upon the input operands S0[i] and S1[i], and to obtain the saturation anticipating signal (saten) that is the AND &E0[i], &E1[i] of the saturation anticipating bit string, thereby making it possible to simplify the logic. Therefore, the circuit scale can be reduced. Further, as for the least significant bit that is outside the representation range of the predetermined bit length, the arithmetic result at the adder 1 is used, so that the difficulty in the anticipation can be avoided, thereby being capable of making a correct anticipation. Moreover, using the algorithm according to this embodiment makes it possible to perform a correct saturation anticipation.

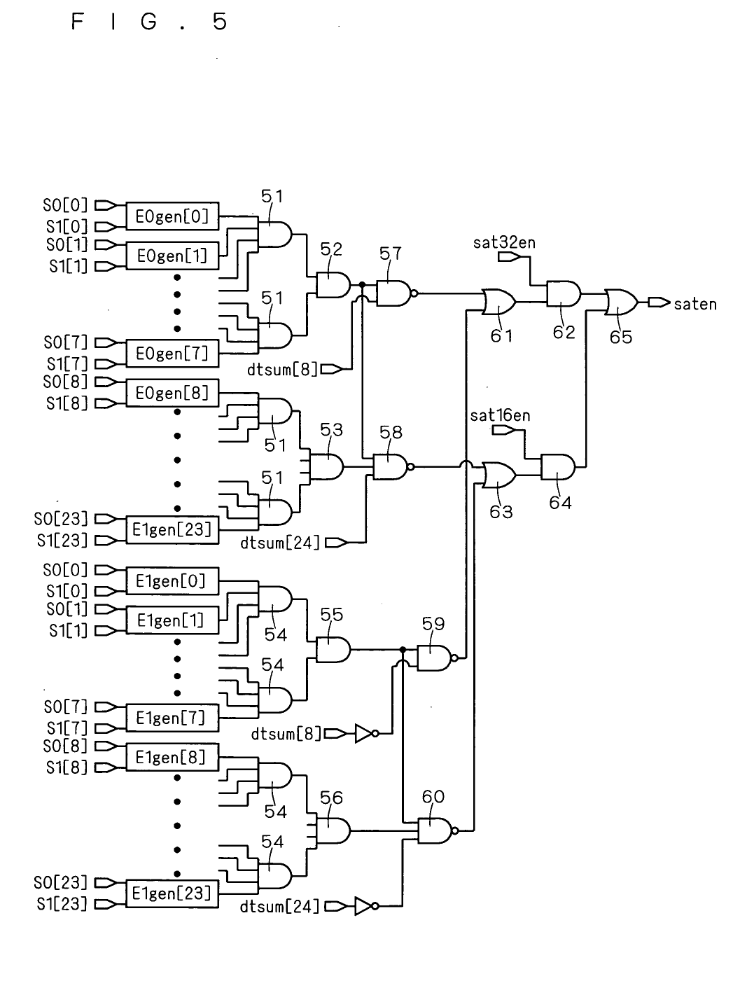

Subsequently, FIG. 3 shows a configuration of a logic circuit operating the Zero anticipating bit E0[i], while FIG. 4 shows a configuration of a logic circuit operating the One anticipating bit E1[i]. Firstly, in FIG. 3, the logic circuit is composed of an XOR circuit 31 that operates the exclusive-OR of the input operands S0[i], S1[i] at ith bit, an NOR circuit 32 that operates NOR of the input operands S0[i+1], S1[i+1] at the (i+1)th bit and an XOR circuit 33 that operates an exclusive-OR of the output from the XOR circuit 31 and the output from the NOR circuit 32.

In FIG. 4, it is composed of an XOR circuit 41 that operates the exclusive-OR of the input operands S0[i], S1[i] at ith bit, an AND circuit 42 that operates AND of the input operands S0[i+1], S1[i+1] at the (i+1)th bit and an XOR circuit 43 that operates an exclusive-OR of the output from the XOR circuit 41 and the output from the AND circuit 42.

The saturation anticipator 2 can be composed by arranging in an array the circuit for operating the Zero anticipating bit E0[i] shown in FIG. 3 and the circuit for operating the One anticipating bit E1[i]. If it is E0[0:23], for example, 24 logic circuits shown in FIG. 3 are arranged, while if it is E1[0:23], 24 logic circuits shown in FIG. 4 are arranged, to compose the saturation anticipator 2.

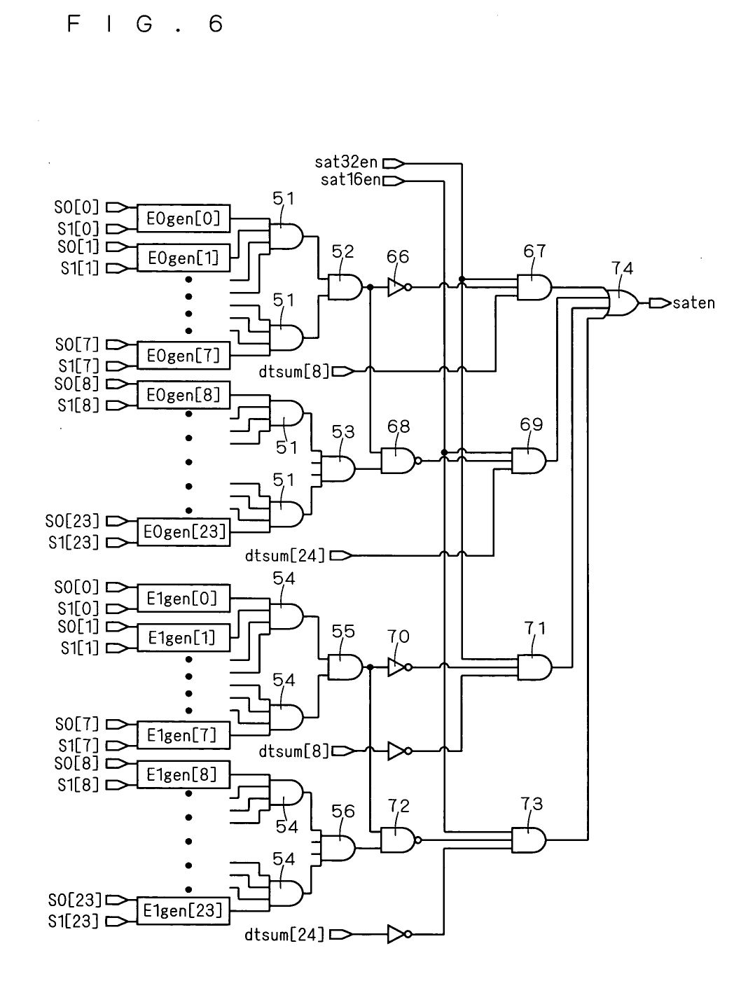

In this embodiment, the enable signals Sat16en, Sat32en are supplied so as to change the representation range to 16-bit length or 32-bit length. FIG. 5 shows the configuration of the saturation anticipator 2 including Sat16en and Sat32en.

In FIG. 5, 24 logic circuits (hereinafter sometimes referred to as E0gen[i] (i is an arbitrary integer)) shown in FIG. 3 are arranged, while 24 logic circuits (hereinafter sometimes referred to as E1gen[i] (i is an arbitrary integer)) shown in FIG. 4 are arranged. At E0gen[i] shown in FIG. 3, four input operands S0[i], S1[i], S0[i+1] and S1[i+1] are required to obtain the Zero anticipating bit E0[i], but the inputs from the input operands S0[i+1] and S1[i+1] are not shown in the figure at E0gen[1] shown in FIG. 5. The same is true for E1gen[i] shown in FIG. 5. The output from E0gen[i] is inputted to the AND circuit 51 every four bit, the outputs from the AND circuit 51 corresponding to E0gen[0] to E0gen[7] are inputted to the AND circuit 52, and the outputs from the AND circuit 51 corresponding to E0gen[8] to E0gen[23] are inputted to the AND circuit 53.

Similarly, the output from E1gen[i] is inputted to the AND circuit 54 every four bit, the outputs from the AND circuit 54 corresponding to E1gen[0] to E1gen[7] are inputted to the AND circuit 55, and the outputs from the AND circuit 54 corresponding to E1gen[8] to E1gen[23] are inputted to the AND circuit 56.

Subsequently, the output from the AND circuit 52 and the dtsum[8] that is the result actually operated at the adder are inputted to the NAND circuit 57 and the outputs from the AND circuits 52 and 53 and the dtsum[24] that is the result actually operated at the adder are inputted to the NAND circuit 58. Similarly, the output from the AND circuit 55 and the inverted result of the dtsum[8] that is the result actually operated at the adder are inputted to the NAND circuit 59 and the outputs from the AND circuits 55 and 56 and the inverted result of the dtsum[24] that is the result actually operated at the adder are inputted to the NAND circuit 60.

The output from the NAND circuit 57 and the output from the NAND circuit 59 are inputted to the OR circuit 61, whereupon the OR circuit 61 outputs the Sat32. The outputs from the NAND circuit 58 and the NAND circuit 60 are inputted to the OR circuit 63, whereupon the OR circuit 63 outputs the Sat16. AND operation of the Sat 32 and the Sat 32en, that is the enable signal, is performed at the AND circuit 62, while AND operation of the Sat 16 and the Sat16en, that is the enable signal, is performed at the AND circuit 64. The OR circuit 65 performs OR operation of the output from the AND circuit 62 and the output from the AND circuit 64, thereby outputting the saten that is the saturation anticipating signal.

As described above, this embodiment adopts the logic circuits of E0gen[i] and E1gen[i] shown in FIGS. 3 and 4 and the configuration of the saturation anticipator 2 shown in FIG. 5, whereby the add operation and the saturation process can be performed in parallel, thereby being capable of attempting to increase the operation speed of the arithmetic unit.

Although this embodiment explains about the case wherein the arithmetic processing section is an adder, the present invention is not limited thereto. The arithmetic processing section may be a subtracter. Further, the arithmetic unit according to the present invention including this embodiment can be applied not only to a general purpose DSP but also to a microprocessor to which a command similar to the command of DSP is added or enhanced dedicated LSI or the like. Further, it is needless to say that the present invention can be applied to a SoC (System On a Chip) product having these mounted thereto.

### Second Embodiment

As explained in the first embodiment, the saturation anticipator 2 shown in FIG. 5 utilizes the dtsum[8] and dtsum[32] that are the outputs from the adder 1. However, if the saturation anticipator 2 has to perform plural processes after obtaining the arithmetic result of the dtsum[8] and dtsum[32] from the adder 1, the process at the saturation anticipator 2 does not complete even after the operation at the adder 1 is completed, even if the adder 1 and the saturation anticipator 2 are driven in parallel. Accordingly, it is considered that the process may be delayed in view of the whole arithmetic unit. Therefore, in this embodiment, the arithmetic result from the adder 1 can be utilized at the later process at the saturation anticipator 2, thereby reducing the process after the arithmetic result is obtained. Consequently, the process speed in view of the whole arithmetic unit can be increased.

Specifically, FIG. 6 shows a view of the configuration of the saturation anticipator 2 according to this embodiment. The components in FIG. 6 same as those in FIG. 5 are given same numerals. Firstly, 24 E0gen[i] are arranged, and 24 E1gen[i] are also arranged in FIG. 6. The output from E0gen[i] is inputted to the AND circuit 51 every four bit, the outputs from the AND circuit 51 corresponding to E0gen[0] to E0gen[7] are inputted to the AND circuit 52, and the outputs from the AND circuit 51 corresponding to E0gen[8] to E0gen[23] are inputted to the AND circuit 53.

Similarly, the output from E1gen[i] is inputted to the AND circuit 54 every four bit, the outputs from the AND circuit 54 corresponding to E1gen[0] to E1gen[7] are inputted to the AND circuit 55, and the outputs from the AND circuit 54 corresponding to E1gen[8] to E1gen[23] are inputted to the AND circuit 56.

Subsequently, the output from the AND circuit 52 that is inverted at an inverter 66, the dtsum[8] that is the result actually operated at the adder and the Sat32en that is the enable signal are inputted to the AND circuit 67. Then, the output from the AND circuit 52 and the output from the AND circuit 53 are inputted to the NAND circuit 68, and the output from the NAND circuit 68, the dtsum[24] that is the result actually operated at the adder and the Sat16en that is the enable signal are inputted to the AND circuit 69. Similarly, the output from the AND circuit 55 that is inverted at an inverter 70, the inversion result of the dtsum[8] that is the result actually operated at the adder and the Sat32en that is the enable signal are inputted to an AND circuit 71. Then, the output from the AND circuit 55 and the output from the AND circuit 56 are inputted to a NAND circuit 72, and the output from the NAND circuit 72, the inversion result of the dtsum[24] that is the result actually operated at the adder and the Sat16en that is the enable signal are inputted to an AND circuit 73.

The output from the AND circuit 67, the output from the AND circuit 69, the output from the AND circuit 71 and the output from the AND circuit 73 are inputted to an OR circuit 74, whereupon the OR circuit 74 outputs the saten that is the saturation anticipating signal.

In the configuration of the saturation anticipator 2 shown in FIG. 6, two arithmetic processes are performed during from when Sat16en, Sat32en, that are enable signals, are inputted to when the saten, that is the saturation anticipating signal, is outputted. On the other hand, in the configuration of the saturation anticipator 2 shown in FIG. 5, four arithmetic processes are performed during from when Sat16en, Sat32en, that are enable signals, are inputted to when the saten, that is the saturation anticipating signal, is outputted. Therefore, the saturation anticipator 2 shown in FIG. 6 can shorten the process during from when Sat16en an Sat32en are inputted to when the saten is outputted, whereby increased speed of the whole arithmetic unit can be achieved.

As described above, this embodiment can achieve increased speed of the whole arithmetic unit by the configuration of the saturation anticipator 2 shown in FIG. 6.

### Third Embodiment

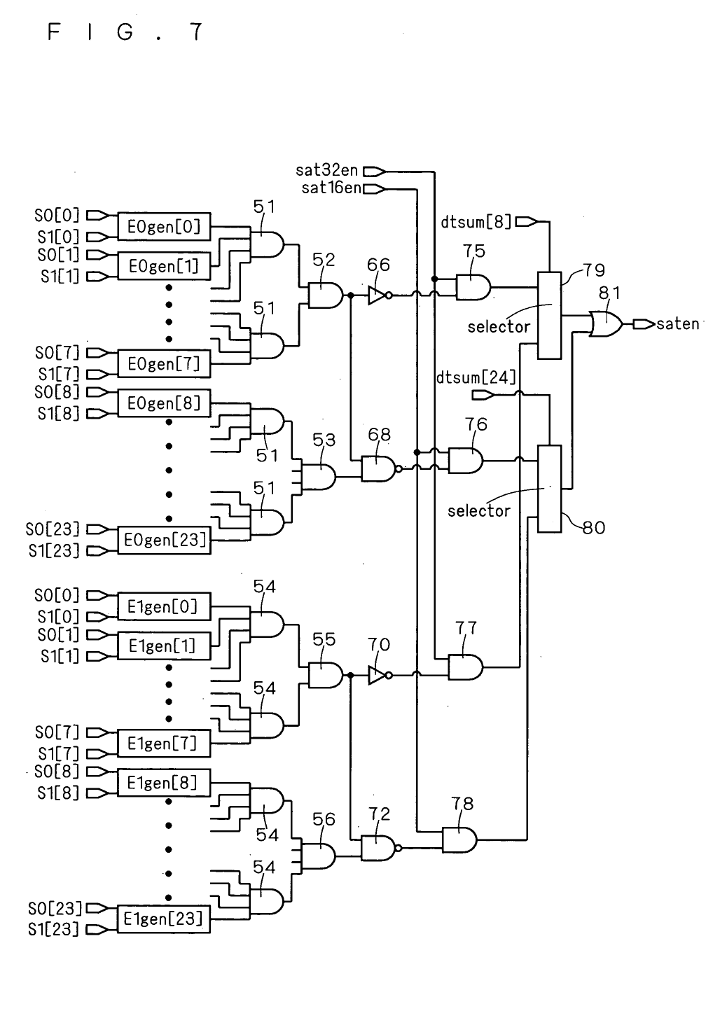

The saturation anticipator 2 according to this embodiment uses a multiplexer, with respect to the saturation anticipator 2 explained in the second embodiment. FIG. 7 shows a view of a specific configuration of the saturation anticipator 2 according to this embodiment. The components in FIG. 7 same as those in FIG. 6 are given same numerals.

Firstly, 24 E0gen[i] are arranged, and 24 E1gen[i] are also arranged in FIG. 7. The output from E0gen[i] is inputted to the AND circuit 51 every four bit, the outputs from the AND circuit 51 corresponding to E0gen[0] to E0gen[7] are inputted to the AND circuit 52, and the outputs from the AND circuit 51 corresponding to E0gen[8] to E0gen[23] are inputted to the AND circuit 53.

Similarly, the output from E1gen[i] is inputted to the AND circuit 54 every four bit, the outputs from the AND circuit 54 corresponding to E1gen[0] to E1gen[7] are inputted to the AND circuit 55, and the outputs from the AND circuit 54 corresponding to E1gen[8] to E1gen[23] are inputted to the AND circuit 56.

Subsequently, the output from the AND circuit 52 that is inverted at the inverter 66 and the Sat32en that is the enable signal are inputted to the AND circuit 75. Then, the output from the AND circuit 52 and the output from the AND circuit 53 are inputted to the NAND circuit 68, and the output from the NAND circuit 68 and the Sat16en that is the enable signal are inputted to the AND circuit 69. Similarly, the output from the AND circuit 55 that is inverted at the inverter 70 and the Sat32en that is the enable signal are inputted to the AND circuit 77. Then, the output from the AND circuit 55 and the output from the AND circuit 56 are inputted to the NAND circuit 72, and the output from the NAND circuit 72 and the Sat16en that is the enable signal are inputted to an AND circuit 78.

The output from the AND circuit 75, the output from the AND circuit 77 and the dtsum[8] that is the result actually operated at the adder are inputted to a first multiplexer 79. Similarly, the output from the AND circuit 76, the output from the AND circuit 78 and the dtsum[24] that is the result actually operated at the adder are inputted to a second multiplexer 80. The output from the first multiplexer 79 and the output from the second multiplexer 80 are inputted to an OR circuit 81, whereupon the OR circuit 81 outputs the saten that is the saturation anticipating signal.

The saturation anticipator 2 according to this embodiment inputs the dtsum[8] and dtsum[24] that are results actually operated at the adder as later as possible, like the saturation anticipator 2 shown in FIG. 6, and uses a multiplexer that can perform a high-speed operation.

As described above, this embodiment can achieve increased speed of the whole arithmetic unit by the configuration of the saturation anticipator 2 shown in FIG. 7.

### Fourth Embodiment

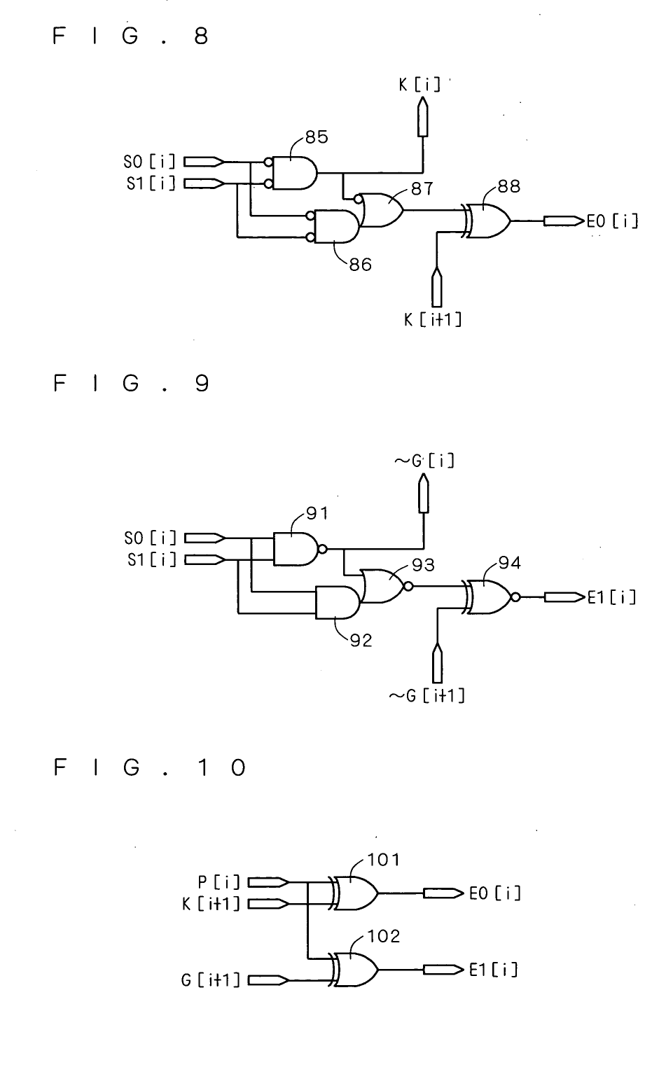

In the first embodiment, the saturation anticipator 2 is composed by using the circuit for operating the Zero anticipating bit E0[i] shown in FIG. 3 and the circuit for operating the One anticipation bit E1[i] shown in FIG. 4. However, as apparent from the figures, four inputs are required in the circuits shown in FIGS. 3 and 4. In order to obtain the Zero anticipating bit E0[0], for example, four inputs, S0[0], S1[0], S0[1] and S1[1], are required. Therefore, it is considered that input fan-in capacity of the circuit for operating the Zero anticipating bit E0[i] or the circuit for operating the One anticipation bit E1[i] is increased, and further, that the circuit scale is increased. In view of this, this embodiment uses a circuit for operating the Zero anticipating bit E0[i] shown in FIG. 8 and a circuit for operating the One anticipating bit E1[i] shown in FIG. 9, instead of the aforesaid circuits.

The logic circuit for operating the Zero anticipating bit E0[i] shown in FIG. 8 is composed of an AND circuit 85 and AND circuit 86 to which the input operands S0[i] and S1[i] are invertedly inputted, an OR circuit 87 to which the output from the AND circuit 86 and the inverted output from the AND circuit 85 are inputted, and an XOR circuit 88 to which Kill signal (K[i+1]) at (i+1)th bit and the output from the OR circuit 87 are inputted. The output from the AND circuit 85 is also outputted as Kill signal (K[i]) at ith bit. Further, the output from the XOR circuit 88 becomes the Zero anticipating bit E0[i].

On the other hand, the logic circuit for operating the One anticipating bit E1[i] shown in FIG. 9 is composed of an NAND circuit 91 and AND circuit 92 to which the input operands S0[i] and S1[i] are inputted, an NOR circuit 93 to which the output from the NAND circuit 91 and the output from the AND circuit 92 are inputted, and an XOR circuit 94 to which an inverse signal of Generate signal (G[i+1]) at (i+1)th bit and the output from the NOR circuit 93 are inputted. The output from the NAND circuit 91 is also outputted as the inverse signal of Generate signal (G[i]) at ith bit. Further, the output from the XOR circuit 94 becomes the Zero anticipating bit E1[i].

As understood from FIGS. 8 and 9, the logic circuits for operating the Zero anticipating bit E0[i] and One anticipating bit E1[i] according to this embodiment require only the input of input operands S0[i] and S1[i], and do not require the input of S0[i+1] and S1[i+1].

As described above, the logic circuits for operating the Zero anticipating bit E0[i] and One anticipating bit E1[i] according to this embodiment have the configurations shown in FIGS. 8 and 9, whereby the input fan-in capacity can be reduced and the circuit scale can also be reduced.

### Fifth Embodiment

The logic circuits for operating the Zero anticipating bit E0[i] and One anticipating bit E1[i] according to the fourth embodiment operate the Zero anticipating bit E0[i] and One anticipating bit E1[i] from the input operands S0[i] and S1[i]. However, the logic circuits for operating the Zero anticipating bit E0[i] and One anticipating bit E1[i] according to this embodiment utilize the Propagate signal, Generate signal and Kill signal at the adder 1, instead of the input operands S0[i] and S1[i].

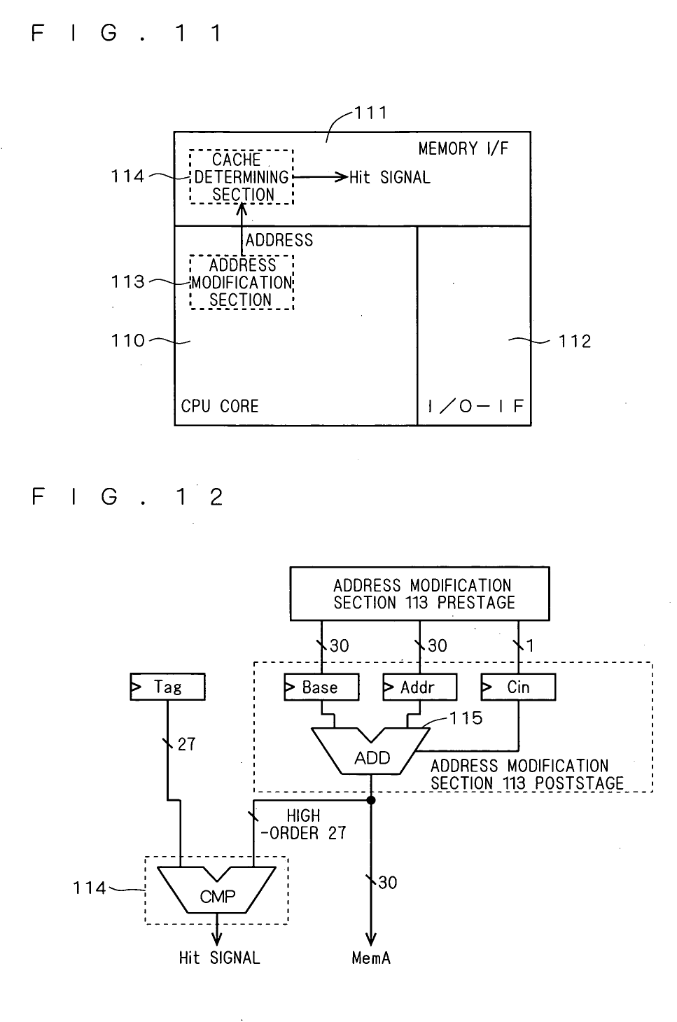

FIG. 10 shows a configuration of a logic circuit for operating the Zero anticipating bit E0[i] and One anticipating bit E1[i] according to this embodiment. The logic circuit shown in FIG. 10 is provided with an XOR circuit 101 to which the Propagate signal (P[i]) at ith bit and Kill signal (K[i+1]) at (i+1)th bit are inputted and an XOR circuit 102 to which the Propagate signal (P[i]) at ith bit and Generate signal (G[i+1]) at (i+1)th bit are inputted. The XOR circuit 101 outputs the Zero anticipating bit E0[i] and XOR circuit 102 outputs the One anticipating bit E1[i].

As described above, the logic circuit for operating the Zero anticipating bit E0[i] and One anticipating bit E1[i] according to this embodiment has the configuration shown in FIG. 10, whereby the circuit scale can be reduced.

### Sixth Embodiment

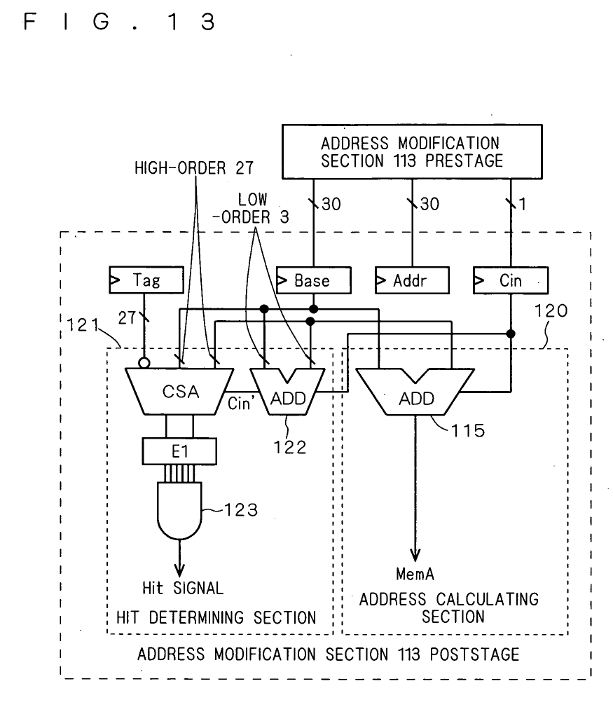

The arithmetic unit explained in the aforesaid embodiments can be applied in various manners. This embodiment explains about the case where the arithmetic unit is applied to a hit determination of a cache memory. Firstly, FIG. 11 shows a layout view of a conventional semiconductor device having a function of a hit determination of a cache memory. The semiconductor device shown in FIG. 11 has a CPU core 110, memory I/F 111 and I/O-IF 112, wherein an address modification section 113 is provided in the CPU core 110 and a cache determining section 114 is provided in the memory I/F 111.

As understood from the layout shown in FIG. 11, the conventional semiconductor device sends the address that is modified at the address modification section 113 to the cache determining section 114, performs the hit determination at the cache determining section 114 and outputs the Hit signal. The address modification section 113 is generally composed of an adder, so that a block diagram of the address modification section 113 and the cache determining section 114 is shown in FIG. 12. Further, the Hit signal is represented by the Formula 9.
MemA[0:29]=Addr[0:29]+Base[0:29]+Cin Hit=(Tag[0:26]=MemA[0:26]) (9)

The operator “==” represented in the Formula 9 means that “1” is returned when the left side and the right side have the same value and “0” is returned in the other conditions. In the following embodiments, the operator “==” is used in the aforesaid meaning.

In the block diagram shown in FIG. 12, a base value (Base), an address value (Addr) after a preprocessing is performed in the case of subtraction and a carry input are generated at the prestage of the address modification section 113, and the resultant is outputted to the poststage of the address modification section 113. The base value (Base) and the address value (Addr) are 30 bits respectively, and they are expressed as Base[0:29] and Addr[0:29] in the Formula 9.

An adder 115 is provided at the poststage of the address modification section 113. A memory address (MemA) is operated from the base value (Base), address value (Addr) and carry input (Cin) inputted to the adder 115. The arithmetic expression at the adder 115 is shown in the Formula 9, wherein the 30-bit memory address (MemA) is expressed as MemA[0:29].

Since the memory address (MemA) after the addition becomes an actual address for a memory access, it is determined at the cache determining section 114 whether this is stored in the cache or not. In FIG. 12, high-order 27 bits of the memory address (MemA) and the target address (Tag) performing the access are compared at a comparator CMP composing the cache determining section 114, and then, the Hit signal is outputted based upon this result. In the Formula 9, the target address (Tag) is expressed as Tag[0:26].

As described above, the adder 115 and the comparator CMP are processed in series in the conventional semiconductor device as shown in FIG. 12, so that the comparator CMP has to wait until the result of the adder 115 is given. Further, both the adder 115 and the comparator CMP have a great delay time. Therefore, there is a problem that the delay for obtaining the Hit signal is great in the hit determination of the cache memory shown in FIG. 12.

In this embodiment, the arithmetic expression shown in the Formula 9 is modified as follows, whereby it can be associated with the One anticipating bit E1 string explained in the first embodiment or the like. Firstly, the Formula 10 represents the modified example of the Formula 9.
Comp_Est0[0:29]=Addr[0:29]+Base[0:29]+Cin−{Tag[0:26],3′h0}Hit=(Comp_Est0[0:26]=27′h0000000) (10)

Subsequently, the equation of the complement of the Formula 10 is represented in the Formula 11.
Comp_Est0[0:29]=Addr[0:29]+Base[0:29]+Cin+^{˜}{Tag[0:26],3′h0}+1′h1Hit=(Comp_Est0[0:26]=27′h0000000) (11)

The Formula 12 is obtained by subtracting 1 from both sides of the Formula 11.
Comp_Est1[0:29]=Addr[0:29]+Base[0:29]+Cin+^{˜}{Tag[0:26],3′h0}Hit=(Comp_Est1[0:26]==27′h7FFFFFF) (12)

Three operands are added at all adders in the Formula 12, but by degenerating this addition to the addition of two operands, the Formula 13 is obtained.
Sum_Est1[0:29]=Addr[0:29]ˆBase[0:29]ˆ^{˜}{Tag[0:26 ],3′h0}Carry_Est1[0:29]=(Addr[0:29]&Base[0:29]) |(Base[0:29]&^{˜}{Tag[0:26],3′h0}) |(^{˜}{Tag[0:26],3′h0}&Addr[0:29]) {Cin′,MemA[27:29]}=Addr[27:29]+Base[27:29]Comp_Est1[0:26]=Sum_Est1[0:26]+Cary_Est1[1:26],Cin′}Hit=(Comp_Est1[0:26]=27′h7FFFFFF) (13)

Each of Comp_Est0, Comp_Est1, Sum_Est1, Cary_Est1 is an intermediate value in the operation at the hit determining section.

The Formula 13 is the one for obtaining whether Comp_Est1[0:26], that is the adding result of Sum_Est1[0:26] and {Cary_Est1[1:26],Cin′}, is All “1” or not. Specifically, Comp_Est1[0:26] corresponds to the One anticipating bit E1 string [0:26], and Sum_Est1[0:26] and {Cary_Est1[1:26],Cin′} respectively correspond to the input operands S0[i] and S1[i] (i is an arbitrary integer), so that the configuration of the first embodiment can be utilized, thereby increasing the speed at the cache determining section 114.

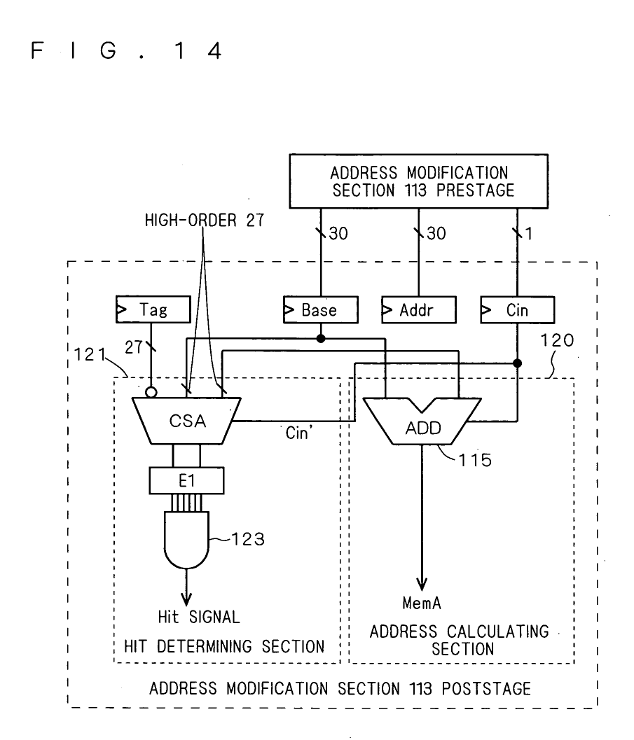

FIG. 13 shows a circuit diagram of the address modification section 113 in case where the Formula 13 is applied. The components in FIG. 13 same as those in FIG. 12 are given same numerals. The base value (Base), address value (Addr) and carry input (Cin) are generated also at the prestage of the address modification section 113, and outputted to the poststage of the address modification section 113.

However, different from FIG. 12, a hit determining section 121 corresponding to the cache determining section 114 is provided at the poststage of the address modification section 113 in FIG. 13. Specifically, the poststage of the address modification section 113 in FIG. 13 is configured such that a dual system of an address calculating section 120 and hit determining section 121 is provided so as to be processed in parallel independently.

At the address calculating section 120, the adder 115 operates the base value (Base), address value (Addr) and carry input (Cin) and outputs the memory address (MemA). The hit determining section 121 has an adder 122 to which low-order 3-bit Addr[27:29] and low-order 3-bit Base[27:29] are inputted and from which carry information Cin′ is outputted, and an arithmetic circuit CSA to which high-order 27-bit Addr[0:26], high-order 27-bit Base[0:26], Tag[0:26] and carry information Cin′ are inputted and from which Comp_Est1[0:26] is outputted.

Further, arithmetic circuits E1, 123 are provided at the hit determining section 121. They are configured to return the Hit signal “1” when Comp_Est1[0:26] takes the same value as 27′hFFFFFF, while return the Hit signal “0” at other state.

The hit determining section 121 according to this embodiment has the arithmetic circuit CSA that is processed in parallel with the address calculating section 120 and is composed of an array wherein all adders have one stage, so that it is unnecessary to transmit the carry input (Cin). Therefore, the poststage of the address modification section 113 according to this embodiment can output the Hit signal with high speed. Accordingly, the hit determining section 121 according to this embodiment can operate in parallel with the address calculating section 120, whereby the hit determination is concealed by the adding process of the address calculation.

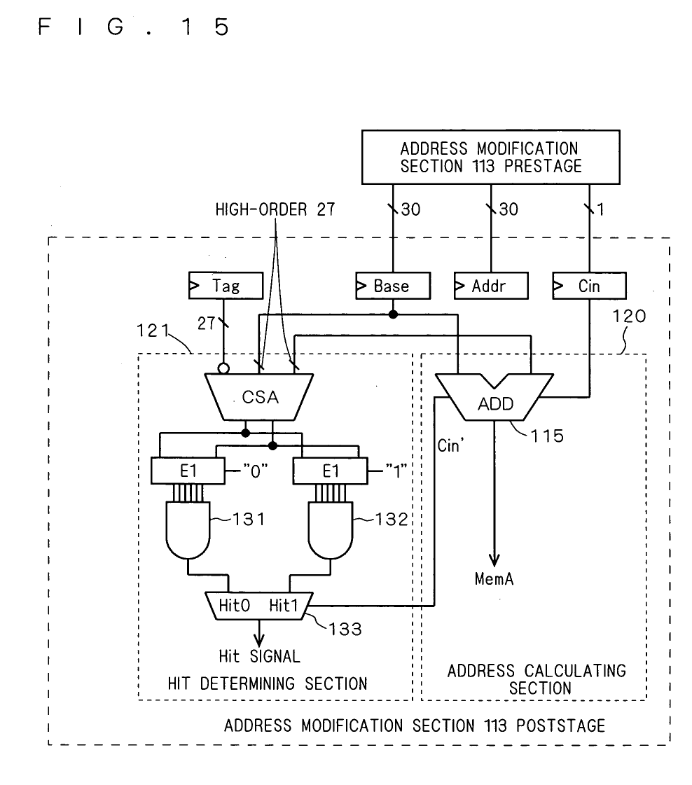

The hit determining section 121 according to this embodiment is provided with the adder 122 for obtaining the carry information Cin′. However, it is understood that the carry information Cin′ is the same as the intermediate value of the address calculating section 120, as understood from the Formula 13 or FIG. 13. Therefore, the value of the carry information Cin′ can be taken out from the adder 115 of the address calculating section 120. FIG. 14 shows a circuit diagram of the address modification section 113 that is the modified example of this embodiment. The circuit diagram in FIG. 14 is the same as that in FIG. 13 except that the adder 122 is not provided at the hit determining section 121. In the arithmetic circuit CSA shown in FIG. 14, the carry information Cin′ is taken out from the adder 115 of the address calculating section 120. Thus, the circuit diagram of the hit determining section 121 can be simplified in the modified example of this embodiment.

### Seventh Embodiment

The sixth embodiment has the configuration wherein the carry information Cin′ is inputted to the arithmetic circuit CSA as shown in FIG. 13. However, the carry information Cin′ is a value obtained by actually operating the Addr[27:29] and Base[27:29] as understood from the Formula 13, so that, in case where the hit determining section 121 and the address calculating section 120 are processed in parallel, the time taken for obtaining the carry information Cin′ becomes the delay time of the parallel process. Specifically, the signal delay is great since the carry information Cin′ involves the carry propagation, so that the path through which the carry information Cin′ passes becomes a critical path in the circuit configuration shown in the sixth embodiment.

In view of this, two types of signals, that are the Hit signal wherein the carry information Cin′ is supposed to be “1” and the Hit signal wherein the carry information Cin′ is supposed to be “0” at the hit determining section 121, are prepared in this embodiment in order that the path through which the carry information Cin′ passes does not become the critical path. This embodiment is configured such that the carry information Cin′ obtained by the actual operation is inputted from the address calculating section 120 to select either one of two Hit signals at the final stage where the operation of the carry information Cin′ has already been completed at the address calculating section 120.

The Formula 14 represents the formula in this embodiment.
Sum_Est1[0:29]=Addr[0:29]ˆBase[0:29]ˆ^{˜}{Tag[0:26],3′h0}Carry_Est1[0:29]=(Addr[0:29]&Base[0:29]) |(Base[0:29]&^{˜}{Tag[0:26],3′h0}) |(^{˜}{Tag[0:26],3′h0}&Addr[0:29]) {Cin′,MemA[27:29]}=Addr[27:29]+Base[27:29]Comp_Est0[0:26]=Sum_Est1[0:26]+Cary_Est1[1:26],1 ′h0}Comp_Est1[0:26]=Sum_Est1[0:26]+Cary_Est1[1:26],1 ′h1}Hit0=(Comp_Est0[0:26]=27′h7FFFFFF) Hit1=(Comp_Est1[0:26]=27′h7FFFFFF) Hit=(Cin′)Hit1:Hit0 (14)

FIG. 15 shows a circuit diagram of the address modification section 113 corresponding to the Formula 14 according to this embodiment. The circuit diagram shown in FIG. 15 is basically the same as that shown in FIG. 14 except that the circuit diagram of the hit determining section 121 is different. Therefore, the components in FIG. 15 same as those in FIG. 14 are given same numerals.

Firstly, high-order 27-bit Addr[0:26], high-order 27-bit Base[0:26] and Tag[0:26] are inputted to the arithmetic circuit CSA. In the arithmetic circuit CSA according to this embodiment, Comp_Est0[0:26] is outputted to the arithmetic circuit E1 wherein the carry information Cin′ is supposed to be “0”, while Comp_Est1[0:26] is outputted to the arithmetic circuit E1 wherein the carry information Cin′ is supposed to be “1”.

Further, the hit determining section 121 shown in FIG. 15 has an arithmetic circuit 131 and arithmetic circuit 132. The arithmetic circuits E1, 131 output the Hit0 signal that returns “1” when Comp_Est0[0:26] takes the same value as 27′hFFFFFF and returns “0” at other state, while the arithmetic circuits E1, 132 output the Hit1 signal that returns “1” when Comp_Est1[0:26] takes the same value as 27′hFFFFFF and returns “0” at other state.

The hit determining section 121 shown in FIG. 15 is provided with a selecting circuit 133 that selects either one of Hit0 signal or Hit1 signal based upon the carry information Cin′ operated at the address calculating section 120. The selecting circuit 133 outputs the Hit0 signal as the Hit signal in case where the carry information Cin′ obtained by the actual operation is “0”, and outputs the Hit1 signal as the Hit signal in case where the carry information Cin′ obtained by the actual operation is “1”.

As described above, the carry information Cin′ obtained by the actual operation is inputted at the poststage of the process at the hit determining section 121, thereby being capable of increasing the speed of the arithmetic unit.

### Eighth Embodiment

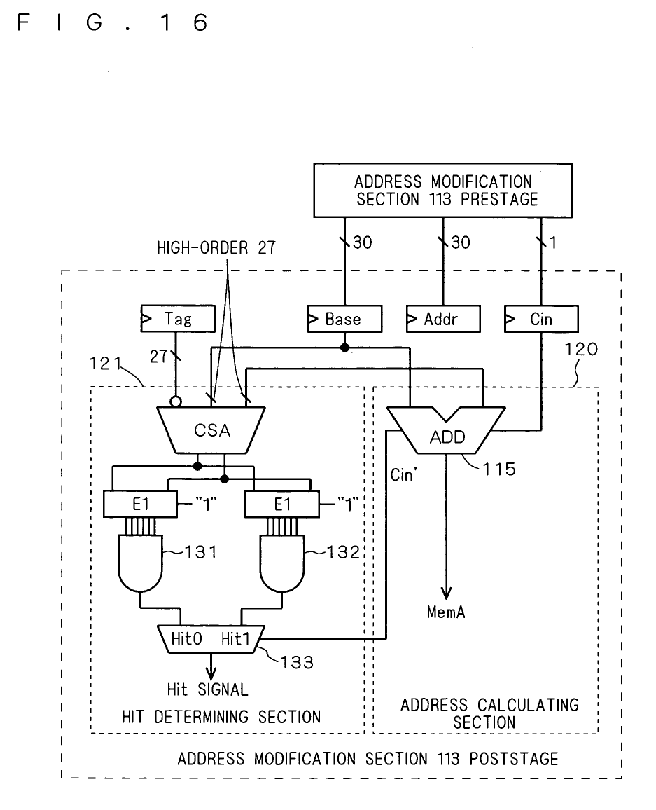

This embodiment is a modified example of the seventh embodiment. FIG. 16 shows its circuit diagram. The circuit diagram shown in FIG. 16 is basically the same as that shown in FIG. 15 except that a part of the hit determining section 121 is different. Therefore, the components shown in FIG. 16 same as those in FIG. 15 are given same numerals.

The arithmetic circuit CSA shown in FIG. 16 utilizes the relationship represented by the following Formula 15 wherein “1” is added to both sides of the determination formula of Comp_Est0[0:26] and Hit0 in the Formula 14.
Comp_Est0[0:26]=Sum_Est1[0:26]+{Cary_Est1[1:26],1′h1}Hit0=(Comp_Est0)[0:26]=27′h0000000) (15)

Comp_Est0[0:26] in the Formula 15 is equal to Comp_Est1[0:26] in the Formula 14. Therefore, different from FIG. 15, the arithmetic circuit CSA shown in FIG. 16 is provided with an arithmetic circuit E0 wherein the carry information Cin′ is supposed to be “1”, instead of the arithmetic circuit E1 wherein the carry information Cin′ is supposed to be “0”.

Further, different from FIG. 15, the arithmetic circuits E0, 131 shown in FIG. 16 have a configuration to output the Hit0 signal that returns “1” when Comp_Est1[0:26] takes the same value as 27′h0000000 and return “0” at other state. The arithmetic circuits E1, 132 output the Hit1 signal that returns “1” when Comp_Est1[0:26] takes the same value as 27′hFFFFFF and return “0” at other state.

The hit determining section 121 shown in FIG. 16 is provided with a selecting circuit 133 that selects either one of Hit0 signal or Hit1 signal based upon the carry information Cin′ operated at the address calculating section 120. The selecting circuit 133 outputs the Hit0 signal as the Hit signal in case where the carry information Cin′ obtained by the actual operation is “0”, and outputs the Hit1 signal as the Hit signal in case where the carry information Cin′ obtained by the actual operation is “1”.

The circuit diagram shown in FIG. 16 is represented by the following Formula 16.
Sum_Est1[0:29]=Addr[0:29]ˆBase[0:29]ˆ^{˜}{Tag[0:26],3′h056 Carry_Est1[0:29]=(Addr[0:29]&Base[0:29]) |(Base[0:29]&^{˜}{Tag[0:26],3′h0}) |(^{˜}{Tag[0:26],3′h0}&Addr[0:29]) {Cin′,MemA[27:29]}=Addr[27:29]+Base[27:29]Comp_Est1[0:26]=Sum_Est1[0:26]+Cary_Est1[1:26],1′h1}Hit0=(Comp_Est1[0:26]==27′h70000000) Hit1=(Comp_Est1[0:26]==27′h7FFFFFF) Hit=(Cin′) Hit1:Hit0 (16)

As described above, the carry information Cin′ obtained by the actual operation is inputted at the poststage of the process at the hit determining section 121, thereby being capable of increasing the speed of the arithmetic unit.

### Ninth Embodiment

The arithmetic unit of the address modification section shown in the embodiments 6 to 8 is particularly effective for a TLB (Translation-lookaside buffer) of a virtual memory system. The TLB is a kind of a cache memory provided for reducing a penalty in the page table reference generated at the conversion from Virtual Address to Physical Address.

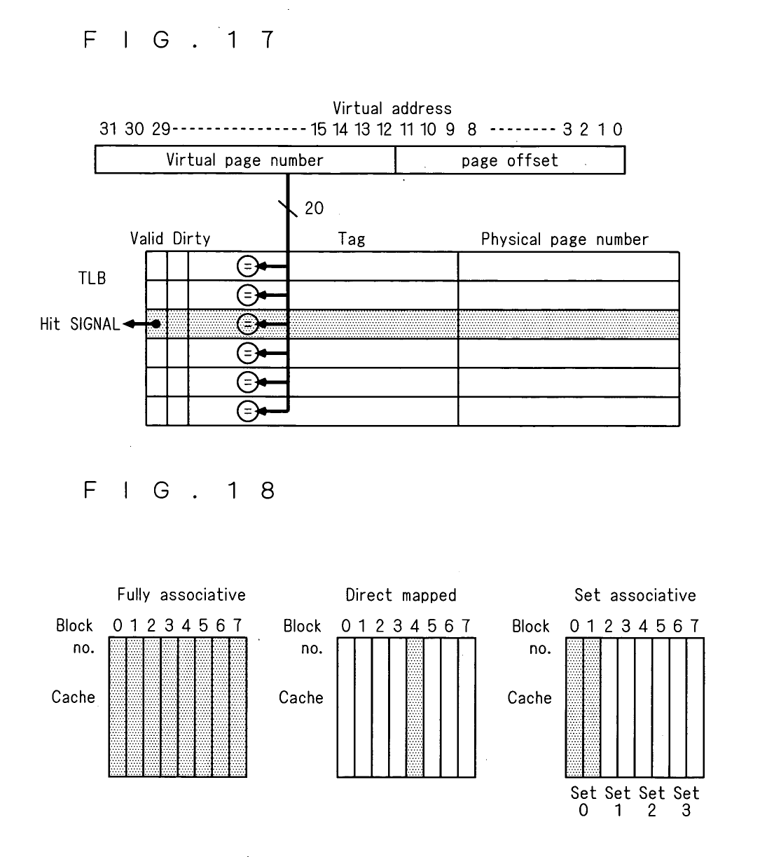

FIG. 17 shows a schematic view of a TLB. The detail is disclosed in D. A. Patterson and J. L. Hennessy, “Computer Organization & Design: The Hardware/Software Interface—Second Edition”, Morgan Kaufmann, 1997, p.593, FIG. 7.25. The TLB shown in FIG. 17 has a structure that compares Virtual Address and Tag. Therefore, the base value (Base) and address value (Addr) explained in the sixth to eighth embodiments are associated with Virtual Address and the target address (Tag) is associated with Tag, respectively, thereby being capable of obtaining the Hit signal of the TLB without a delay.

### Tenth Embodiment

The arithmetic unit of the address modification section disclosed in the sixth to eighth embodiments is also particularly effective for a Fully Associative type cache.

As shown in FIG. 18, there are three types, i.e., Direct Map type, Set Associative type and Fully Associative type, in the cache memory. Direct Map type is a system wherein a position on a cache at each block is uniquely decided. Set Associative type is a system wherein a block is placed only within a certain determined range on a cache. Fully Associative type is a system wherein a block is placed at an arbitrary position on a cache. The detail of three types of a cache memory is disclosed in J. L. Hennessy and D. A. Patterson, “Computer Architecture: A Quantitative Approach—Third Edition”, Morgan Kaufmann, 2003, p. 398, FIG. 5.4.

As understood from FIG. 18, the target address (Tag) is read out from each block of a memory device in Direct Map type or Set Associative type, so that a delay occurs in its access. If this delay is sufficiently small, the effects shown in the sixth to eighth embodiments are provided, but if this delay is great so as to be equal to the address calculation, the address calculating time is concealed in this memory access time. However, the target address (Tag) is always read out from a unique block of a memory device in Fully Associative type, so that a delay does not occur in the memory access. Therefore, the effects shown in the sixth to eighth embodiments can be obtained.

While the invention has been shown and described in detail, the foregoing description is in all aspects illustrative and not restrictive. It is therefore understood that numerous modifications and variations can be devised without departing from the scope of the invention.

What is claimed is:

1. An arithmetic unit comprising:
an arithmetic processing section that performs an adding or subtracting operation of a first input operand and a second input operand and outputs the arithmetic result;
a saturation anticipating section that anticipates whether said arithmetic result is within a representation range of a predetermined bit length based upon said first input operand and said second input operand, and outputs a saturation anticipating signal; and
a selecting section that selects that the maximum value or minimum value within the representation range of the predetermined bit length is made to be the output result in case where said arithmetic result is anticipated not to be within the representation range of the predetermined bit length in said saturation anticipating signal from said saturation anticipating section, and selects that said arithmetic result is made to be said output result in case where said arithmetic result is anticipated to be within the representation range of the predetermined bit length in said saturation anticipating signal, wherein
said saturation anticipating section is operated in parallel with respect to said arithmetic processing section.

2. The arithmetic unit according to claim 1, wherein said saturation anticipating section generates a saturation anticipating bit string that anticipates an individual bit state of said arithmetic result positioned at the outside of the representation range of the predetermined bit length based upon said first input operand and said second input operand, to thereby obtain said saturation anticipating signal that is an AND of the saturation anticipating bit string.

3. The arithmetic unit according to claim 2, wherein
said saturation anticipating bit string has a Zero anticipating bit string anticipating that the individual bit state of said arithmetic result positioned at the outside of the representation range of the predetermined bit length is “0” and a One anticipating bit string anticipating that the individual bit state of said arithmetic result positioned at the outside of the representation range of the predetermined bit length is “1”, and
said saturation anticipating section obtains said saturation anticipating signal by operating the OR of the AND of said Zero anticipating bit string and the AND of said One anticipating bit string.

4. The arithmetic unit according to claim 3, wherein
said Zero anticipating bit string and said One anticipating bit string use said arithmetic result for each least significant bit.

5. The arithmetic unit according to claim 3, wherein
said saturation anticipating section has:
a first algorithm for obtaining said Zero anticipating bit string by operating the exclusive-OR of a Propagate signal, that is the exclusive-OR of said first input operand and said second input operand, and a Kill signal, that is 1-bit lower from said Propagate signal and is obtained by inverting the OR of said first input operand and said second input operand; and
a second algorithm for obtaining said One anticipating bit string by operating the exclusive-OR of said Propagate signal and a Generate signal, that is 1-bit lower from said Propagate signal and said AND of the first input operand and said second input operand.

6. The arithmetic unit according to claim 5, capable of selecting the representation range of the first bit length and the representation range of a second bit length that is narrower than that of said first bit length, wherein
said saturation anticipating section includes:
a Zero anticipating bit processing section that performs said first algorithm process to bits of said first input operand and said second input operand except for the least significant bit outside the representation range of said second bit length, thereby outputting said Zero anticipating bit string;
a One anticipating bit processing section that performs said second algorithm process to bits of said first input operand and said second input operand except for the least significant bit outside the representation range of said second bit length, thereby outputting said Zero anticipating bit string;
a first logical operation section that operates the AND of bits of the output from said Zero anticipating bit processing section except for the least significant bit outside the representation range of said first bit length;
a second logical operation section that operates the AND with respect to the output from said Zero anticipating bit processing section except for the bit operated at said first logical operation section;
a third logical operation section that operates the AND of bits of the output from said One anticipating bit processing section except for the least significant bit outside the representation range of said first bit length;
a fourth logical operation section that operates the AND with respect to the output from said One anticipating bit processing section except for the bit operated at said third logical operation section;
a first least significant bit operation section that operates the NAND of the output from the first logical operation section and said arithmetic result corresponding to the least significant bit outside the representation range of said first bit length;
a second least significant bit operation section that operates the NAND of the output from the first logical operation section, the output from the second logical operation section and said arithmetic result corresponding to the least significant bit outside the representation range of said second bit length;
a third least significant bit operation section that operates the NAND of the output from the third logical operation section and the bit obtained by inverting said arithmetic result corresponding to the least significant bit outside the representation range of said first bit length;
a fourth least significant bit operation section that operates the NAND of the output from the third logical operation section, the output from the fourth logical operation section and the bit obtained by inverting said arithmetic result corresponding to the least significant bit outside the representation range of said second bit length;
a first saturation anticipating bit operation section that obtains the OR of the first least significant bit operation section and the third least significant bit operation section as a first saturation anticipating bit with respect to the representation range of said first bit length;
a second saturation anticipating bit operation section that obtains the OR of the second least significant bit operation section and the fourth least significant bit operation section as a second saturation anticipating bit with respect to the representation range of said second bit length;
a first enable signal operation section that operates the AND of said first saturation anticipating bit and a first enable signal indicating whether the representation range of said first bit length is selected or not;
a second enable signal operation section that operates the AND of said second saturation anticipating bit and a second enable signal indicating whether the representation range of said second bit length is selected or not; and
a first saturation anticipating signal outputting section that operates the OR of the output from said first enable signal operation section and the output from said second enable signal operation section, to thereby output said saturation anticipating signal.

7. The arithmetic unit according to claim 6, wherein
said saturation anticipating section includes, instead of said first to fourth least significant bit operation sections, first and second saturation anticipating bit operation sections, first and second enable signal operation sections and first saturation anticipating signal outputting section:
a first inverter that inverts the output from said first logical operation section;
a first NAND operation section that operates the NAND of the output from said first logical operation section and the output from said second logical operation section;
a second inverter that inverts the output from said third logical operation section;
a second NAND operation section that operates the NAND of the output from said third logical operation section and the output from said fourth logical operation section;
a first operation section that operates the AND of said first enable signal, the output from said first inverter and said arithmetic result corresponding to the least significant bit outside the representation range of said first bit length;
a second operation section that operates the AND of said second enable signal, the output from said first NAND operation section and said arithmetic result corresponding to the least significant bit outside the representation range of said second bit length;
a third operation section that operates the AND of the output from said enable signal outputting section, the output from said second inverter and the bit obtained by inverting said arithmetic result corresponding to the least significant bit outside the representation range of said first bit length;
a fourth operation section that operates the AND of said second enable signal, the output from said second NAND operation section and the bit obtained by inverting said arithmetic result corresponding to the least significant bit outside the representation range of said second bit length; and
a second saturation anticipating signal outputting section that operates the OR of the outputs from said first to fourth operation sections, to thereby output said saturation anticipating signal.

8. The arithmetic unit according to claim 7, wherein
said saturation anticipating section includes, instead of said first to fourth operation sections and said second saturation anticipating signal outputting section:
a fifth operation section that operates the AND of said first enable signal and the output from said first inverter;
a sixth operation section that operates the AND of said second enable signal and the output from said first NAND operation section;
a seventh operation section that operates the AND of said first enable signal and the output from said second inverter;
an eighth operation section that operates the AND of said second enable signal and the output from said second NAND operation section;
a first multiplexer section that processes the output from said fifth operation section, the output from said seventh operation section and said arithmetic result corresponding to the least significant bit outside the representation range of said first bit length;
a second multiplexer section that processes the output from said sixth operation section, the output from said eighth operation section and said arithmetic result corresponding to the least significant bit outside the representation range of said second bit length; and
a third saturation anticipating signal outputting section that operates the OR of the output from said first multiplexer and the output from said second multiplexer, thereby outputting said saturation anticipating signal.

9. The arithmetic unit according to claim 6, wherein
said Zero anticipating bit processing section includes:
a first operand operation section that operates the exclusive-OR of said first input operand and said second input operand;
a second operand operation section that operates the NOR of said first input operand and said second input operand that are one bit lower from said first input operand and said second input operand inputted to said first input operand operation section; and
a third operand operation section that operates the exclusive-OR of the output from said first operand operation section and the output from said second operand section, and
said One anticipation bit processing section includes:
a fourth operand operation section that operates the exclusive-OR of said first input operand and said second input operand;
a fifth operand operation section that operates the NOR of said first input operand and said second input operand that are one bit lower from said first input operand and said second input operand inputted to said first input operand operation section; and
a sixth operand operation section that operates the exclusive-OR of the output from said fourth operand section and the output from said fifth operand operation section.

10. The arithmetic unit according to claim 6, wherein
said Zero anticipating processing section includes:
seventh and eighth operand operation sections that operate the AND of said inverted first input operand and said second input operand;
a ninth operand operation section that operates the OR of the inverted output from said seventh operand operation section and the output from said eighth operand operation section; and
a tenth operand operation section that operates the exclusive-OR of the output from said ninth operand operation section and the output from said seventh operand operation section that corresponds to one bit lower, and
said One anticipating bit processing section includes:
an eleventh operand operation section that operates the NAND of said first input operand and said second input operand;
a twelfth operand operation section that operates the AND of said first input operand and said second input operand;
a thirteenth operand operation section that operates the NOR of the output from the eleventh operand operation section and the output from the twelfth operand operation section; and
a fourteenth operand operation section that operates the exclusive-NOR of the output from said thirteenth operand operation section and the output from said eleventh operand operation section that corresponds to one bit lower.

11. The arithmetic unit according to claim 9, wherein
said Zero anticipating bit processing section is not provided with said first and second operand operation sections, and inputs the Propagate signal operated at said arithmetic processing section and the Kill signal that is one bit lower from said Propagate signal and operated at said arithmetic processing section to said third operand operation section, instead of the outputs from said first and the second operand operation sections, and
said One anticipating bit processing section is not provided with said fourth and fifth operand operation sections, and inputs the Propagate signal operated at said arithmetic processing section and the Generate signal that is one bit lower from said Propagate signal and operated at said arithmetic processing section to said sixth operand operation section, instead of the outputs from said fourth and the fifth operand operation sections.

12. An arithmetic unit used for an address modification section of a memory, comprising:
an address calculating section that operates a memory address based upon a base value and address value that have been subject to a predetermined process and first carry information; and
a hit determining section that determines whether the target address that performs an access and said memory address agree with each other or not based upon second carry information operated from a predetermined low-order bit of said base value and said address value and said first carry information and a predetermined high-order bit of said base value and said address value, and outputs the determination result as a Hit signal, wherein
said hit determining section is operated in parallel with respect to said address calculating section.

13. The arithmetic unit according to claim 12, wherein
said hit determining section obtains a One anticipating bit string, that decides the state of said Hit signal depending upon whether all of the individual bit states are “1” or not, by operating said second carry information, the predetermined high-order bit of said base value and said address value and said target address.

14. The arithmetic unit according to claim 13, wherein
said address calculating section supplies to said hit determining section the arithmetic result obtained by operating the predetermined low-order bit of said base value and said address value and said first carry information as said second carry information.

15. The arithmetic unit according to claim 14, wherein
said hit determining section obtains beforehand by the operation said One anticipating bit string wherein said second carry information is supposed to be “0” and said One anticipating bit string wherein said second carry information is supposed to be “1”, and selects either one of said One anticipating bit string at the point when said second carry information is supplied from said address calculating section, thereby outputting said Hit signal.

16. The arithmetic unit according to claim 14, wherein
said hit determining section further obtains the Zero anticipating bit string that decides the state of said Hit signal depending upon whether all of the individual bit states are “0” by operating said second carry information, the predetermined high-order bit of said base value and said address value and said target address, and selects either one of said One anticipating bit string and said Zero anticipating bit string at the point when said second carry information is supplied from said address calculating section, thereby outputting said Hit signal.

17. The arithmetic unit according to claim 12, which is used for a TLB of a virtual memory system.

18. The arithmetic unit according to claim 12, which is used for a Fully Associative cache.
